(19) United States
(12) Patent Application Publication
(10) Pub. No.: US 2024/0194779 A1
(43) Pub. Date: Jun. 13, 2024

(54) SEMICONDUCTOR DEVICE AND METHOD OF PRODUCING THEREOF

(71) Applicant: Infineon Technologies Austria AG, Villach (AT)

(72) Inventors: Christian Zmölnig, Wien (AT); Markus Kahn, Rangersdorf (AT); Juergen Steinbrenner, Nötsch im Gailtal (AT); Oliver Humbel, Maria Elend (AT); Angelika Koprowski, Klagenfurt (AT); Thomas Kurzmann, Müchen (DE)

(21) Appl. No.: 18/522,816

(22) Filed: Nov. 29, 2023

(30) Foreign Application Priority Data
Dec. 7, 2022 (DE) 102022213199.1

(51) Int. Cl. H01L 29/78; H01L 29/06

(52) U.S. Cl. CPC H01L 29/7811; H01L 29/0611; H01L 29/7395

(57) ABSTRACT

The application refers to a semiconductor device including: a semiconductor body having a first surface and a second surface; an active region having at least one semiconductor cell configured to conduct a load current between the first surface and the second surface; an edge termination region separating the active region from a chip edge; and a first layer within at least a part of the edge termination region. The first layer includes silicon, nitrogen and hydrogen. In atomic numbers, a ratio of the silicon to the nitrogen is at least 3.3 to 4 in at least a portion of the first layer. At least the portion of the first layer includes at most 16 percent hydrogen in atomic numbers.

### TECHNICAL FIELD

The present disclosure relates to the field of semiconductor devices and, in particular, to power semiconductor devices comprising a specific layer structure at the edge termination region, and to methods of producing thereof.

### BACKGROUND

Semiconductor devices in general and, in particular, high-power modules like IGBT diodes and MOSFETs, are sensitive to harsh environmental conditions. The packaging applied sometimes does not protect the power electronics from environmental influences. Increased humidity level and temperature variation can lead to drastic changes in the material properties and blocking behavior of the semiconductor devices.

Therefore, there is a need of improving external stress resistance and lifetime characteristics of semiconductor devices.

A power semiconductor device usually comprises a semiconductor body configured to conduct a forward load current along a load current path between two load terminals of the device.

Further, in case of a controllable power semiconductor device, e.g., a transistor, the load current path may be controlled by means of an insulated electrode, commonly referred to as gate electrode. For example, upon receiving a corresponding control signal from, e.g., a driver unit, the control electrode may set the power semiconductor device in one of a forward conducting state and a blocking state.

The load current is typically conducted by means of an active region of the power semiconductor device. The active region is typically surrounded by an edge termination region, which is terminated by an edge of the chip.

The edge termination region is typically not used for load current conduction purposes, but to safely terminate the active region and guarantee robust blocking characteristics of the device.

At one side of the chip, e.g., the frontside, the electrical potentials of both load terminals may be present, and the edge termination region may provide for electrical path between these electrical potentials. With respect to the primary function of the edge termination region, namely, to safely terminate the active region, it may be desirable to provide for a distinct voltage course between these electrical potentials within the edge termination region.

### SUMMARY

According to an embodiment, a semiconductor device comprises a semiconductor body comprising a first surface and a second surface. The semiconductor device further comprises an active region comprising at least one semiconductor cell configured to conduct a load current between the first surface and the second surface and an edge termination region separating the active region from a chip edge. The semiconductor device further comprises a first layer within at least a part of the edge termination region, the first layer comprising silicon, nitrogen and hydrogen, wherein, in atomic numbers, a ratio of silicon to nitrogen is at least 3.3 to 4 in at least a portion of the first layer and wherein at least the portion of the first layer comprises at most 16 percent hydrogen in atomic numbers.

According to another embodiment, a semiconductor device comprises a semiconductor body comprising a first surface and a second surface. The semiconductor device further comprises an active region comprising at least one semiconductor cell configured to conduct a load current between the first surface and the second surface and an edge termination region separating the active region from a chip edge. The semiconductor device further comprises a first layer within the edge termination region, the first layer comprising silicon, nitrogen and hydrogen, wherein an electrical conductivity of the first layer exhibits a local or global maximum between 273K and 373K and/or wherein the electrical conductivity of the first layer exhibits a falling slope with increasing at a specified maximum working temperature.

According to another embodiment, a semiconductor device comprises a semiconductor body comprising a first surface and a second surface. The semiconductor device further comprises an active region comprising at least one semiconductor cell configured to conduct a load current between the first surface and the second surface and an edge termination region separating the active region from a chip edge. The semiconductor device further comprises a first layer and a second layer. The first layer is arranged at least within the edge termination region, the first layer comprising silicon, nitrogen and hydrogen. The second layer is arranged at least within the edge termination region, the second layer comprising silicon, nitrogen and hydrogen. In atomic numbers, a ratio of silicon to nitrogen is at least 10 percent higher in the first layer than in the second layer. For example, both the first layer and the second layer may comprise less than 16 percent or even less than 13 percent hydrogen atoms.

According to another embodiment, a semiconductor device comprises a semiconductor body comprising a first surface and a second surface; a first load terminal arranged on the first surface and a second load terminal arranged on the second surface; an active region comprising at least one semiconductor cell configured to conduct a load current between the first load terminal and the second load terminal; a chip edge bordering the first surface and the second surface; and an edge termination region arranged between the active region and the chip edge. Within at least a part of the edge termination region, the semiconductor device comprises a first layer comprising silicon, nitrogen and hydrogen, wherein, in at least a portion of the first layer, a number of silicon atoms is greater than 82.5% of a number of nitrogen atoms, wherein of all the silicon atoms, nitrogen atoms and hydrogen atoms within at least the portion of the first layer at most 16% are hydrogen atoms.

According to another embodiment, a method of producing a power semiconductor device comprises following steps: Providing a semiconductor body comprising a first surface and a second surface, an active region comprising at least one semiconductor cell configured to conduct a load current between the first surface and the second surface, and an edge termination region separating the active region from a chip edge. Forming a first layer within at least a part of the edge termination region, the first layer comprising silicon, nitrogen and hydrogen, wherein, in atomic numbers, a ratio of silicon to nitrogen is at least 3.3 to 4 in at least a portion of the first layer wherein at least the portion of the first layer comprises at most 16 percent hydrogen in atomic numbers.

According to another embodiment, a method of producing a power semiconductor device comprises following steps: Proving a semiconductor body comprising a first surface and a second surface, an active region comprising at least one semiconductor cell configured to conduct a load current between the first surface and the second surface, and an edge termination region separating the active region from a chip edge. Forming a first layer within the edge termination region, the first layer comprising silicon, nitrogen and hydrogen, wherein an electrical conductivity of the first layer exhibits a local or global maximum between 273K and 373K and/or wherein the electrical conductivity of the first layer exhibits a falling slope with increasing at a specified maximum working temperature.

According to another embodiment, a method of producing a power semiconductor device comprises following steps: Providing a semiconductor body comprising a first surface and a second surface, an active region comprising at least one semiconductor cell configured to conduct a load current between the first surface and the second surface, and an edge termination region separating the active region from a chip edge. Forming a first layer within the edge termination region, the first layer comprising silicon, nitrogen and hydrogen and forming a second layer within the edge termination region, the second layer comprising silicon, nitrogen and hydrogen, wherein, in atomic numbers, a ratio of silicon to nitrogen is at least 10 percent higher in the first layer than in the second layer.

According to another embodiment, a method of producing a power semiconductor device comprises following steps: Providing a semiconductor body comprising a first surface and a second surface, a first load terminal arranged on the first surface and a second load terminal arranged on the second surface, an active region comprising at least one semiconductor cell configured to conduct a load current between the first load terminal and the second load terminal, a chip edge bordering the first surface and the second surface and an edge termination region arranged between the active region and the chip edge, the edge termination region comprising an edge termination structure. Forming, above the first load terminal and/or above the edge termination structure, a first layer comprising silicon, nitrogen and hydrogen, wherein, in at least a portion of the first layer, a number of silicon atoms is greater than 82.5% of a number of nitrogen atoms; wherein of all the silicon atoms, nitrogen atoms and hydrogen atoms within at least the portion of the first layer at most 16% are hydrogen atoms.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a cross sectional view of an embodiment of a power semiconductor device comprising a first layer within at least a part of the edge termination region as described herein.

FIG. 2 illustrates a cross sectional view of an embodiment of a power semiconductor device comprising a first layer within at least a part of the edge termination region as described herein.

FIG. 3 illustrates a cross sectional view of a further embodiment of a power semiconductor device comprising a first layer within at least a part of the edge termination region as described herein.

FIGS. 4A through 4F schematically illustrate various further embodiments with different configurations of the first layer of a power semiconductor described herein.

FIG. 5 schematically illustrates one further embodiment of a power semiconductor described herein.

FIG. 6 by way of example illustrates a temperature dependency of the electrical conductivity of the first layer.

FIG. 7 by way of example illustrates a ratio of different elements within the first layer and an optional second layer.

### DETAILED DESCRIPTION

The examples described herein provide a power semiconductor device (in the following description also mentioned as semiconductor device). The power semiconductor device comprises a semiconductor body with a first surface and a second surface. The power semiconductor device has an active region comprising at least one semiconductor cell configured to conduct a load current between the first surface and the second surface. The power semiconductor device comprises an edge termination region separating the active region from a chip edge. Furthermore, the power semiconductor device comprises a first layer which is described in detail below.

In this specification, the term “above” does mean that a layer is applied on the surface of these device structures or regions or via one or more other structures or layers. Thereby the thin film layer may be directly on the device structures or regions or may extend directly onto another layer or element. Intervening layers or elements may also be present. In contrast, when a layer or an element is referred to as being “directly on” or extending “directly onto” another layer or element, there are no intervening layers or elements present.

The semiconductor device, such as a high voltage semiconductor device (e.g. a semiconductor chip) may, for example, be configured as an IGBT (Insulated Gate Bipolar Transistor), a FET (Field Effect Transistor), in particular a MOSFET (Metal Oxide Semiconductor FET), a JFET (Junction Gate FET), a thyristor, specifically a GTO (Gate Turn-Off) thyristor, a BJT (Bipolar Junction Transistor), an HEMT (High Electron Mobility Transistor), or a diode. By way of example, a source electrode and a gate electrode of, e.g., a FET or MOSFET may be situated on the top side surface, while the drain electrode of the FET or MOSFET may be arranged on the bottom side surface.

The semiconductor body may comprise a semiconductor substrate, e.g. a processed wafer or a wafer with epitaxial layers comprising several device structures on or over a surface of the wafer. The semiconductor substrate may comprise or be of a semiconductor material such as, e.g., Si, SiC, SiGe, GaAs, GaN, AlGaN, InGaAs, InAlAs, etc. For instance, the semiconductor substrate may be a wafer or a chip comprising an active region. The active region may comprise at least one semiconductor cell configured to conduct a load current between the first load terminal and the second load terminal arranged on the first and second surfaces thereof, respectively. For instance, the first and second load terminals may be formed by a high voltage electrically conductive structure, which is, e.g., made of metal. All kinds of metal or metal alloy may be used for the load terminals, though in many cases the metal may comprise or be of aluminum or copper or an alloy of aluminum or copper. Examples of the load terminals are set out further below. It is to be noted that load terminals may be located relatively close to the anode of the active region so as to be subjected to high electrical fields during operation of the semiconductor device. The load terminals may be configured to be applied with a high voltage of equal to or greater than 0.6 kV, 1 KV, 2 kV, 3 kV or 4 KV or 5 KV or 6 kV or 6.5 kV during operation. This voltage may be applied between a first load terminal (e.g. anode, source, emitter or another electrically conductive structure connected with the first load terminal) and a second load terminal of the power semiconductor device (e.g. a cathode, drain or collector at the bottom side of the semiconductor body) arranged, e.g., at a surface of the semiconductor body opposite to the surface of the semiconductor body where the first load terminal is provided. The voltage applied between the first and second load terminal may, for example, also be referred to as “load voltage”, “emitter collector voltage”, or “source drain voltage”.

An edge termination region may be between the active region and a chip edge of the semiconductor body, e. g. near the first surface. For example, the edge termination region may be arranged within the semiconductor body in proximity to the first surface or adjoining the first surface. The chip edge may be a lateral border of the semiconductor body. The chip edge may be a cutting edge resulting from separating the semiconductor body from a wafer during manufacture. The chip edge may indicate the border between the first surface and the second surface of the semiconductor body. In some examples, the chip edge may also define the boarder to a neighboring chip on a wafer substrate. Two or more such chips may be placed on a single wafer, and each may have chip edges related to its neighboring chips. The edge termination region, thus, helps to separate the chips integrated on one wafer. Moreover, the edge termination region can be used to facilitate the separation of the individual chips within the edge termination region when slicing the individual chips from a wafer with a number of chips during manufacturing of the semiconductor device.

The first layer may, according to different aspects of the invention, be arranged within the active region of the power semiconductor device and/or within the edge termination region of the power semiconductor device. For example, the first layer may be arranged (partly or only) within the edge termination region, e.g. above an edge termination structure. The first layer may comprise silicon, nitrogen and hydrogen. The first layer may comprise or consist of a modified form of stoichiometric silicon nitride, with increased content of silicon.

The first layer may be characterized by its composition. For example, in at least a portion of the first layer (or the complete first layer) a ratio of silicon to nitrogen is at least 3.3 to 4, in atomic numbers, and at least the portion of the first layer (or the complete first layer) comprises at most 16 percent hydrogen in atomic numbers. In another example, the ratio of silicon to nitrogen within the first layer may be at least 3.6 to 4 in atomic numbers. For example, the first layer comprises at most 14 percent hydrogen or at most 12 percent hydrogen in atomic numbers. For example, in least a portion of the first layer, a number of silicon atoms is greater than 82.5% of a number of nitrogen atoms and of all the silicon atoms, nitrogen atoms and hydrogen atoms within at least the portion of the first layer at most 16% (or 14% or 12%) are hydrogen atoms.

Alternatively or additionally, the first layer may be characterized by its composition relative to a second layer, wherein the second layer also comprises silicon, nitrogen and hydrogen. The second layer may comprise or consist of stoichiometric silicon nitride or a variant of stoichiometric silicon nitride with smaller deviation from the composition of stoichiometric silicon nitride than the first layer. For example, the composition of the (optional) second layer may be more similar to the composition of stoichiometric silicon nitride than the composition of the first layer. This may especially apply to the atomic number of silicon, nitrogen and hydrogen. For example, in atomic numbers, a ratio of silicon to nitrogen in the second layer is lower than in the first layer. In other words, for every nitrogen atom the number of accompanying silicon atoms is greater in the first layer than in the second layer. The first layer therefore comprises relatively more silicon than the second layer. For example, a ratio of silicon to nitrogen in atomic numbers may be at least 10 percent or even at least 20 percent higher in the first layer than in the second layer. The second layer may have a lower electrical conductivity than the first layer. The second layer may comprise, in atomic numbers, (substantially) the same or a lower amount of hydrogen compared to the first layer. In another example, the second layer may comprise, in atomic numbers, at most 10 percent more hydrogen than the first layer or less. For example, the upper bound for the hydrogen content of the second layer, in atomic numbers, may be 110 percent of the hydrogen content of the first layer. For example, the second layer may comprise, in atomic numbers, less than 16 percent hydrogen atoms. In another example, the second layer may comprise (in atomic numbers) less than 14 percent or even less than 12 percent hydrogen atoms. For example, both the first layer and the second layer may comprise less than 16 percent or even less than 14 or 12 percent hydrogen atoms. The second layer may be arranged adjoining the first layer. The second layer may be arranged above the first layer. The first and the second layer may be formed during a single deposition process, wherein the different stoichiometry of both layers results from changing the ratio of educts during the single deposition process.

The electrical conductivity of the first layer may be increasing with increasing temperature in a temperature interval from 250 K to 300 K. For example, the electrical conductivity of the first layer at 423 K is at least 150% or even 200% of the electrical conductivity of the first layer at 323 K. In other words, the electrical conductivity may increase by the factor of 1.5 or even the factor of 2 in the when heating the first layer from 323 K to 423 K.

Alternatively or additionally, the first layer may be characterized by its electrical properties. For example, an electrical conductivity of the first layer exhibits a local or global maximum between 273K and 373K. For example, the electrical conductivity of the first layer exhibits a falling slope with increasing at a specified maximum working temperature. The specified maximum working temperature may be within a range between 150° C. (or 423 K) and 250° C. (or 523 K), for example 175° C. (or 448 K). The electrical conductivity of the first layer may be increasing with increasing temperature in a temperature interval from 250 K to 300 K. For example, the electrical conductivity of the first layer at 423 K is at least 150% or even 200% of the electrical conductivity of the first layer at 323 K. In other words, the electrical conductivity may increase by the factor of 1.5 or even the factor of 2 in the when heating the first layer from 323 K to 423 K.

For example, the first layer comprises a conductivity of at most 5×10⁻³ S. For example, the semiconductor device of one of the preceding claims, wherein the first layer comprises a conductivity of at least 1×10⁻⁴ S. According to another example, the first layer comprises a conductivity of at least 2×10⁻² S.

For example, the first layer (or at least a portion of the first layer) may be in direct contact to the semiconductor body or, in other words, adjoin the semiconductor body. Alternatively, the first layer may be arranged at least partly (or completely) above an optional third layer. In this case, at least a portion of the third layer may be in direct contact to the semiconductor body. At least a portion of the first layer may be in direct contact to the third layer. For example, the first layer may be arranged directly above the third layer. The third layer may be an insulator with greater resistivity than the first layer. For example, the third layer may be an oxide, e.g. silicon oxide. The third layer may comprise a locally oxidized silicon (LOCOS) and/or gate oxide.

The first layer may comprise a thickness of 40 nm to 800 nm. Alternatively, the first layer may comprise a thickness of 80 nm to 330 nm. The first layer may be formed as a contiguous layer. The first layer may be the only layer of the semiconductor device of its specific chemical composition. For example, no other layer or part of the semiconductor device may have the same chemical composition or stoichiometry as the first layer.

For example, a first portion of the first layer is connected to an electrically conductive first structure, the first structure having the same potential as a first load terminal arranged on the first surface of the semiconductor body. For example, the electrically conductive first structure may be electrically connected to the first load terminal or be part of the first load terminal. For example, the first structure may be made of metal or highly conductive polysilicon.

For example, a second portion of the first layer is connected to an electrically conductive second structure, the second structure having the same potential as a second load terminal arranged on the second surface of the semiconductor body. For example, the electrically conductive second structure may be electrically connected to the second load terminal or have the same potential as the second load terminal. For example, the electrically conductive second structure may be electrically connected to a channel stopper or have the same potential as the channel stopper. For example, the second structure may be made of metal or highly conductive polysilicon. The second structure may be closer to the chip edge than the first structure.

The first layer may form a high-ohmic conducive path between the first structure and the second structure. In other words, a high-ohmic conducive path between the first structure and the second structure may be provided by the first layer. In a blocking state of the power semiconductor device, a small leakage current may flow along the first layer or, respectively, the high-ohmic conducive path. With this small leakage current a portion of the semiconductor device below the first layer may be shielded against (outer) charges (or outer charge carriers). Outer charges could otherwise lower the breakdown voltage of the device. In case the first layer is arranged within the edge termination region or, respectively, above (at least a portion of) the edge termination structure, the respective portion may be shielded and thus a lowering of the breakthrough voltage of the edge termination by the other charges may be prevented.

For example, the first layer is the uppermost layer in the edge termination region or, respectively, above the edge termination structure. However, even if the first layer is the uppermost layer in the edge termination region there may still be an imide coating above the first layer as the coating is not part of a layer structure. For example, the first layer may be the uppermost hard passivation layer in the edge termination region or, respectively, above the edge termination structure. According to this example, only soft passivation layers, e.g., the imide coating or a resin (epoxy) based coating, may be arranged above the first layer. The first layer may be the uppermost barrier layer in the edge termination region. For example, the first layer is the uppermost humidity barrier in the edge termination region with no additional humidity resistant or impermeable layer above the first layer. In other words, there may be no other humidity resistant or humidity impermeable layer above the first layer. Alternatively or additionally, the first layer is the uppermost ion barrier layer in the edge termination region with no additional ion resistant or ion impermeable layer above the first layer.

In the following, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged within the active region of the power semiconductor device.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

The present specification in particular relates to a power semiconductor device embodied as a diode, a MOSFET or IGBT, i.e., a unipolar or bipolar power semiconductor transistor or diode or a derivate thereof.

For example, the power semiconductor device described below may be a single semiconductor chip, e.g., exhibiting a stripe cell configuration (or a cellular/needle cell configuration) and can be configured to be employed as a power component in a low-, medium- and/or high voltage application. However, the herein proposed technical teaching may also be applied to a power semiconductor device having a cellular/needle cell configuration.

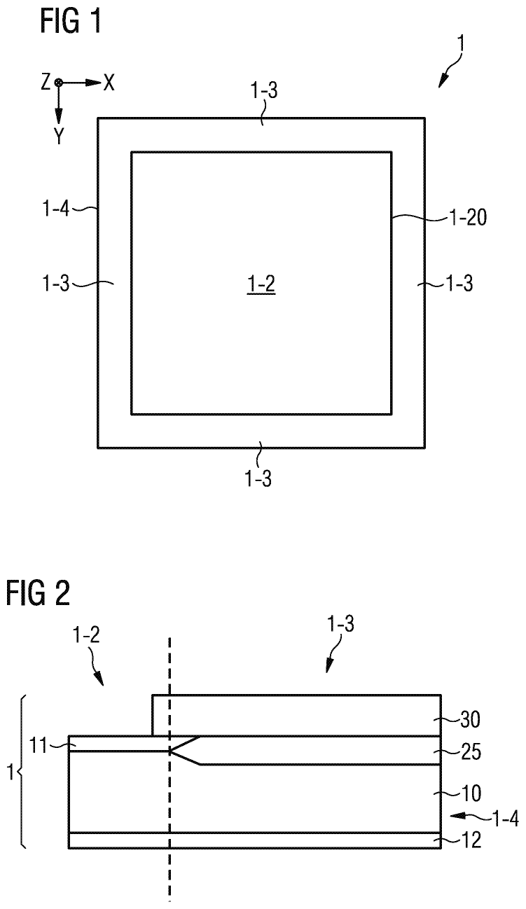

FIG. 1 illustrates a section of a horizontal projection of a power semiconductor device 1 in accordance with one or more embodiments. The power semiconductor device 1 exhibits, for example, an IGBT-configuration or a diode-configuration or an RC-IGBT-configuration. The power semiconductor device 1 comprises a semiconductor body 10 coupled to a first load terminal 11 and a second load terminal 12. An active region 1-2 is configured to conduct a load current between the first load terminal 11 and the second load terminal 12. The semiconductor body 10 may comprise a drift zone of a first conductivity type.

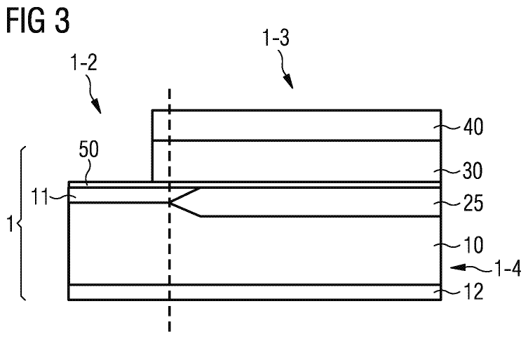

As illustrated, e.g. in FIG. 2, the semiconductor body 10 may be sandwiched between the first load terminal 11 and the second load terminal 12. Hence, the power semiconductor device 1 may exhibit a vertical configuration, according to which the load current follows a path substantially in parallel to the vertical direction Z. The active region 1-2 may be confined by a border 1-20 where the active region 1-2 transitions into the edge termination region 1-3, which is in turn terminated by the chip edge 1-4. Within the edge termination region 1-3 the power semiconductor device 1 comprises an edge termination structure 25. The edge termination structure 25 may be arranged at least partly within the semiconductor body 10, e.g. adjacent to the first surface or the frontside of the power semiconductor device 1.

Herein, the terms ‘active region’ and ‘edge termination region’ are used in a technical context the skilled person typically associates with these terms. Accordingly, the purpose of the active region 1-2 is primarily to ensure load current conduction, whereas the edge termination region 1-3 is configured to reliably terminate the active region 1-2, e.g. in terms of courses of the electric field during conduction state and during blocking state.

At the first surface of the semiconductor body 10, e.g., the frontside of the power semiconductor device 1, the electrical potentials of both load terminals 11, 12 may be present, and the edge termination region 1-3 may be configured to balance between these electrical potentials, e.g. to prevent an electric breakthrough. For example, at the chip edge 1-4 the electrical potentials of the second load terminal 12 may be present along the full vertical extension of the semiconductor body 10. Along the edge termination region 1-3, or, respectively, along the edge termination structure 25, the electrical potential may transition from the potential of the first load terminal 11 to the potential of the second load terminal 12. This may particularly apply to the lateral extension of the edge termination region 1-3 or, respectively, the edge termination structure 25. For example, on a first side of the edge termination region 1-3, or, respectively, of the edge termination structure 25, the potential is equal or similar to the potential of the first load terminal 11 and on a second side of the edge termination region 1-3, or, respectively, of the edge termination structure 25, the potential is equal or similar to the potential of the second load terminal 12. Said first side is closer to the active region 1-2 while said second side is closer to the chip edge 1-4.

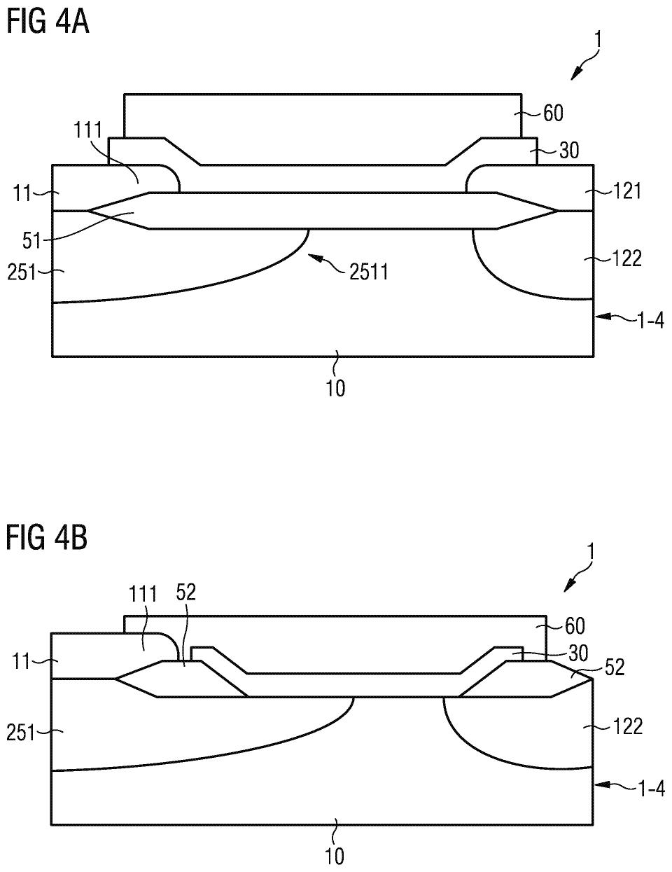

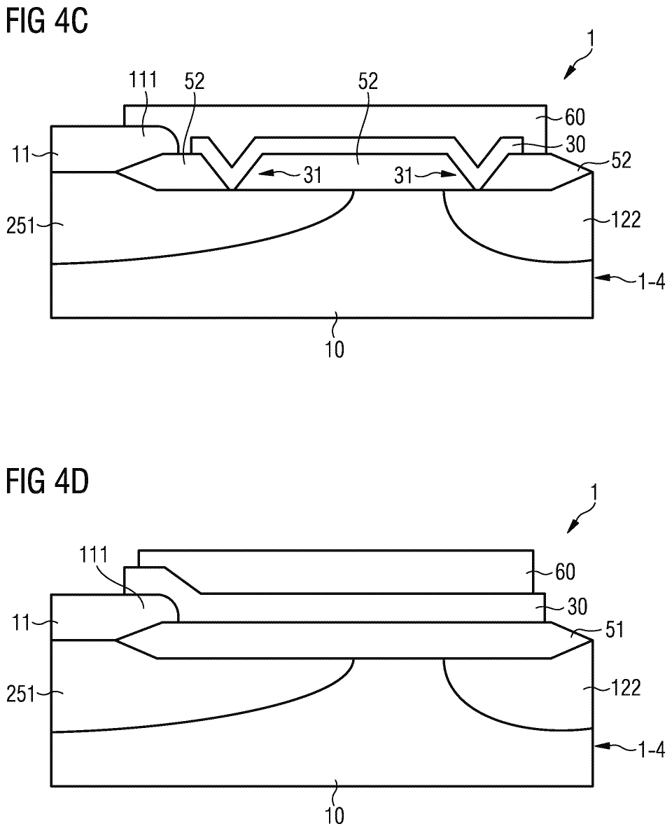

Within at least a part of the edge termination region 1-3, the semiconductor device 1 comprises the first layer 30. The first layer 30 may be arranged only within the edge termination region 1-3 or extend into the active region 1-2. According to some embodiments, the first layer 30 may be arranged only within the active region 1-2. This is shown in FIGS. 2 and 3 in a very schematic way. In the following, FIGS. 4A to 4F show more detailed embodiments with various implementations of the first layer 30. The first layer 30 is arranged above the semiconductor body 10.

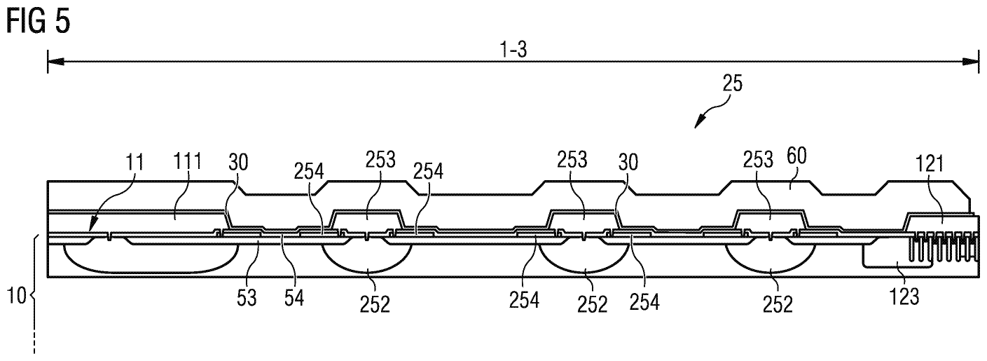

According to some embodiments according to FIGS. 2 to 4F, the first layer 30 comprises, in atomic numbers, a ratio of silicon to nitrogen of at least 3.3 to 4 and at most 16 percent or even at most 13 percent hydrogen in atomic numbers. According to some embodiments, an electrical conductivity of the first layer 30 exhibits a local or global maximum between 273K and 373K. According to some embodiments, the electrical conductivity of the first layer 30 exhibits a falling slope with increasing at a specified maximum working temperature. The specified maximum working temperature may be within a range between 150° C. (or 423 K) and 250° C. (or 523 K), for example 175° C. (or 448 K). The electrical conductivity of the first layer 30 is shown as an example in FIG. 6. Of course, the course of the graph is only an example and does not limit the scope of the invention.

According to the embodiment of FIG. 2, the first layer 30 is arranged directly above the semiconductor body 10 and adjoins the semiconductor body 10. The first layer 30 is the uppermost layer of the semiconductor derive 1 in the edge termination region 1-3 or, respectively, above the edge termination structure 25. However, even with the first layer 30 being the uppermost layer in the edge termination region 1-3 there may still be an imide coating 60 (as depicted in FIGS. 4 A to 4 F) above the first layer 30 as the imide coating 60 is not considered a layer due to the lack of a layer shape. The first layer 30 is therefore the uppermost barrier layer in the edge termination region 1-3. The first layer 30 may therefore be used as passivation layer.

Now referring to the embodiment of FIG. 3, the semiconductor device 1 comprises an additional second layer 40, wherein the second layer 40 also comprises silicon, nitrogen and hydrogen. A ratio of silicon to nitrogen in the second layer 40 is lower than in the first layer 30 in atomic numbers. The first layer 30 therefore comprises relatively more silicon than the second layer 40. For example, a ratio of silicon to nitrogen in atomic numbers may be at least 10 percent or even at least 20 percent higher in the first layer 30 than in the second layer 40. The second layer 40 may have a lower electrical conductivity than the first layer 30. The second layer 40 comprises less than 16 percent or even less than 13 percent hydrogen atoms. According to embodiments, both the first layer 30 and the second layer 40 comprise less than 16 percent or even less than 13 percent hydrogen atoms. The second layer 40 is arranged above the first layer 30 and adjoins the first layer 30. The second layer 40 may be an additional passivation layer. The second layer 40 may be arranged only within the edge termination region 1-3 or extend into the active region 1-2.

Furthermore, according to the embodiment of FIG. 3, the semiconductor device 1 comprises an additional third layer 50. The third layer 50 comprises silicon oxide. The third layer 50 may consist of a same material or even be the same layer as a gate oxide provided in the active region 1-2. The third layer 50 may comprise locally oxidized silicon (LOCOS). The first layer 30 is arranged above the third layer 50. At least a portion of the first layer 30 contacts the third layer 50. The third layer 50 may electrically insulate the first layer against the semiconductor body 10. The third layer 50 and the first layer 30 may be formed during a single deposition process, wherein the different stoichiometry of both layers 30, 50 results from changing the educts and/or ratio of educts during the single deposition process. Furthermore, the second layer 40 may (optionally) also be formed during the same single deposition process. In this case, all three layers, first, second, and third layer, 30, 40, 50 may be formed during a single deposition process.

Now referring to FIGS. 4A to 4F, some similarities among the various embodiments depicted therein are explained. The edge termination region 1-3 or, respectively, the edge termination structure 25 comprises a VLD (variation of lateral doping) zone 251. Within the VLD zone 251, a dopant concentration of a second conductivity type (opposite to the first conductivity type) may be lower with decreasing distance to the chip edge 1-4, e.g. in increments or continuously. The VLD zone 251 may comprise a portion with increasing dopant concentration of the first conductivity type towards the chip edge 1-4, e.g. in increments or continuously. However, VLD zones are widely known so a detailed description is deemed expendable.

The first layer 30 may be arranged at least partly above the VLD zone 251. The first layer 30 may be laterally centered around an outer edge 2511 of the VLD zone 251. The outer edge 2511 may be the edge of the VLD zone 251 closest to the chip edge 1-4. This may shield a part of the chip, the outer edge 2511, vulnerable to charges outside the chip to a special degree thus lowering the vulnerably to electrical break through.

On the second side of the edge termination region 1-3, the semiconductor device 1 comprises a doped region 122 of the first conductivity type. The doped region may be a channel stopper. As described above in general, the doped region 122 may have the potential of the second load terminal 12. Alternatively or additionally, the semiconductor device 1 may comprise a metal structure 121 close to the chip edge 1-4 and on the second side of the edge termination region 1-3. The doped region 122 and/or the metal structure 121 may be considered an electrically conductive second structure exhibiting the potential of the second load terminal 12 during operation of the semiconductor device. In operation of the semiconductor device 1, the load voltage may be applied between the first load terminal 11 and the doped region 122 and/or the metal structure 121.

The semiconductor device 1 also comprises an electrically conductive first structure 111 electrically connected to the first load terminal 11. The electrically conductive first structure 111 has the potential of the first load terminal 11. In the embodiments of FIG. 4A to 4F, the first structure 111 is part of the first load terminal 11. In operation of the semiconductor device 1, the load voltage may be applied between the first structure 111 and the doped region 122 and/or the metal structure 121.

Still referring to FIGS. 4A to 4F, the first layer 30 is the uppermost layer of the semiconductor derive 1 in the edge termination region 1-3 or, respectively, above the VLD zone 251. However, even with the first layer 30 being the uppermost layer in the edge termination region 1-3 there is an imide coating 60 above the first layer 30 as the imide coating 60 is not considered a layer due to the lack of a layer shape. According to the examples, the first layer 30 is the uppermost hard passivation layer in the edge termination region 1-3 and above the edge termination structure 25. Accordingly, only a soft passivation layer—the imide coating 60—is arranged above the first layer 30. The first layer 30 is therefore the uppermost barrier layer in the edge termination region 1-3. The first layer 30 may therefore be used as passivation layer. Different examples of a third layer are provided by layers 51 and 52.

According to the embodiment of FIG. 4A, the first layer 30 is arranged above a LOCOS (locally oxidized silicon) layer 51. Layer 51 continuously extends from the first structure 111 to the doped region 122 and/or the metal structure 121. The first layer 30 continuously extends from the first structure 111 to the doped region 122 and/or the metal structure 121. Hence the first layer 30 provides a homogeneous high-ohmic conductive path between the first structure 111 or, respectively, the first load terminal 11 and an electrically conductive second structure as the metal structure 121 to the doped region 122.

According to the embodiment of FIG. 4B, the first layer 30 is in direct contact to the semiconductor body 10. So at least a portion of the first layer 30 is arranged directly above the semiconductor body 10. However, another portion, or, as depicted more another portion, of the first layer 30 is arranged above oxide layers 52. The oxide layer 52 may or may not electrically insulate the first layer 30 against channel stopper 122. There is a gap between the first structure 111 (or respectively the first load terminal 11) and the first layer 30, so the first structure 111 (or respectively the first load terminal 11) and the first layer 30 do not adjoin each other. Hence, there is no electric connection between the first structure 111 (or respectively the first load terminal 11) and the first layer 30.

According to the embodiment of FIG. 4C, there also is a gap between the first structure 111 (or respectively the first load terminal 11) and the first layer 30. The first layer 30 is arranged above an oxide layer 52 predominantly, e.g. for at least 80 percent or even at least 90 percent of its lateral extension. However, portions of the first layer 30 bulge into the oxide layer 52. The bulges 31 may extend at least partly along the vertical direction Z. First layer 30 may comprise a constant thickness along bulges 31. A bulge 31 may fully extend through oxide layer 52, physically separating it into separate portions. Bulges 31 may physically contact the semiconductor body. Even a high-ohmic conductive path through the first layer 30 to a portion of the semiconductor device 1 may established by electrical connection provided by a bulge 31. In the present example, channel stopper 122 and VLD zone 251 may be connected by high-ohmic conductive path through the first layer 30 via the bulges 31.

The embodiment of FIG. 4D is similar to the embodiment of FIG. 4A, comprising a greater number of bulges 31. The embodiment of FIG. 4F, the first layer 30 may comprise more than two or more than three bulges 31, e.g. five bulges 31. Each of the bulges 31 may physically and/or electrically contact the semiconductor body 10.

The embodiment of FIG. 4D is similar to the embodiment of FIG. 4A. According to the embodiment of FIG. 4D, no metal structure 121 is arranged above the cannel stopper 122. Unlike in FIG. 4A, no connection of the first layer 30 to the potential of the second load terminal 12 is provided. The first layer 30 is electrically connected only to the first structure 111 (or respectively the first load terminal 11).

According to the embodiment of FIG. 4E, the first layer 30 is arranged above a LOCOS layer 51 (similar to FIG. 4A). The first layer 30 is electrically floating. Layer 51 continuously extends from the first structure 111 to the doped region 122 and/or the metal structure 121. The first layer 30 is fully arrange above the oxide layer 51. Oxide layer 51 provides electrical insulation of the first layer against the semiconductor body 10 along the complete lateral extension of the first layer 30. There is a gap between the first structure 111 (or respectively the first load terminal 11) and the first layer 30, so the first structure 111 (or respectively the first load terminal 11) and the first layer 30 do not adjoin each other. Hence, there is no electric connection between the first structure 111 (or respectively the first load terminal 11) and the first layer 30. There is a gap between the metal structure 121 and the first layer 30, so the metal structure 121 and the first layer 30 do not adjoin each other. Hence, there is no electric connection between the metal structure 121 and the first layer 30. Electrical insulation between the channel stopper 122 and the first layer 30 is provided by the oxide layer 51. The rest of the first layer 30 is encapsulated by the imide coating 60.

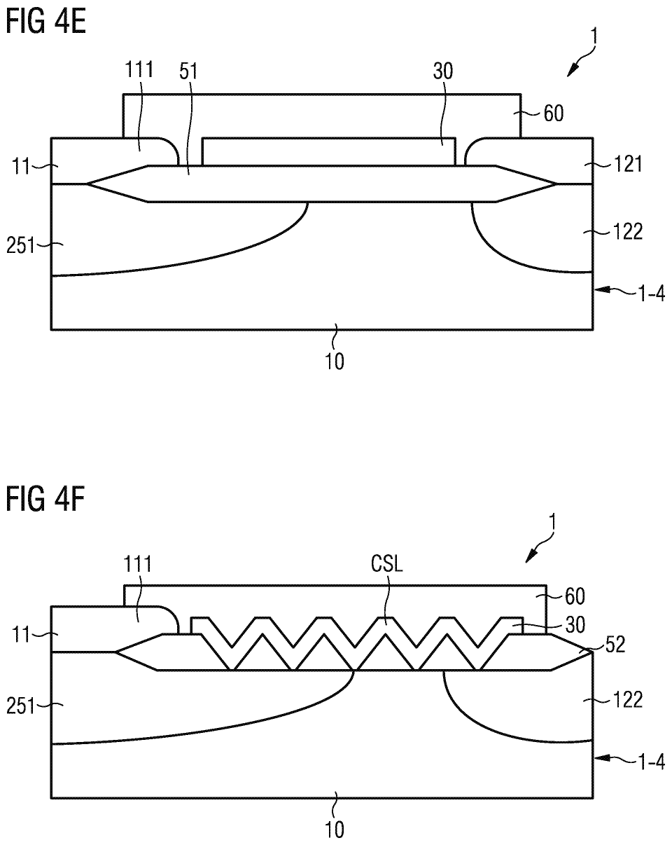

Another example of an edge termination structure 25 is a ring type edge termination, e.g. a p-ring edge termination, as depicted in FIG. 5. According to the embodiments, the edge termination structure 25 includes a plurality of semiconductor regions 252 of the second conductivity type. Each of the semiconductor regions 252 may be connected with a respective field plate 253, which is arranged above the semiconductor body 10. Each of the semiconductor regions 252 may encompass the active region 1-2. The field plates 253 may be insulated against the semiconductor body 10 by one or more insulating layers 53, 54. At least one or both of the layers 53, 54 may comprise an oxide or nitride, e.g. silicon oxide or silicon nitride. For example, contact plugs or via may extend through the at least one insulating layer 53, 54. The field plates 253 may comprise an electrically conductive material, e.g. a metal or a highly doped polysilicon. In the depicted embodiment, the edge termination structure 25 comprises further field plates 254 sandwiched between insulating layer 53, 54 and electrically connected to a respective one of the field plates 253.

According to the embodiments, the semiconductor device 1 furthers comprise a metal structure 121 close to the chip edge 1-4 and on the second side of the edge termination region 1-3 and a doped region 123 below the metal structure 121. The doped region 123 below the metal structure 121 exhibit the potential of the second load terminal 12 during operation of the semiconductor device. In operation of the semiconductor device 1, the load voltage is applied between the first load terminal 11 (or electrically conductive first structure 111 respectively) and the doped region 122 and/or the metal structure 121.

The first layer 30 is arranged above the field plates 253 and above the at least one insulating layer 53, 54. The first layer 30 forms a high-ohmic path connecting the metal structure 121 and the first load terminal 11. Furthermore, the field plates 253 are connected to the high-ohmic path between the metal structure 121 and the first load terminal 11. The high-ohmic path may provide a defined distribution potential of the field plates 253, the metal structure 121 and the first load terminal 11 relative to each other. The load voltage is distributed between the field plates 253, the metal structure 121 and the first load terminal 11 along the high-ohmic path provided by the first layer 30 in a defined way.

In FIG. 6 an exemplary graph of the conductivity σ on the y-axis against the temperate T on the x-axis is depicted. The conductivity σ is given in Siemens while the temperature T is given in Kelvin (K). It should be noted, however, that this graph is only an example without limiting the scope of the present application. Also, very differing distribution of the conductivity σ in dependency of the temperature T are possible. The electrical conductivity σ of the first layer 30 may be increasing with increasing temperature T in a temperature interval from 250 K to 300 K. For example, the electrical conductivity σ of the first layer 30 at 423 K is at least 150% or even 200% of the electrical conductivity σ of the first layer 30 at 323 K. In other words, the electrical conductivity σ may increase by the factor of 1.5 or even the factor of 2 in the when heating the first layer 30 from 323 K to 423 K.

Still referring to FIG. 6, an electrical conductivity σ of the first layer 30 exhibits a local or global maximum between 273 K and 373 K. For example, the electrical conductivity σ of the first layer 30 exhibits a falling slope with increasing at a specified maximum working temperature. The specified maximum working temperature may be within a range between 150° C. (or 423 K) and 250° C. (or 523 K), for example 175° C. (or 448 K). The electrical conductivity σ of the first layer 30 may be increasing with increasing temperature in a temperature interval from 250 K to 300 K. For example, the electrical conductivity σ of the first layer 30 at 423 K is at least 150% or even 200% of the electrical conductivity σ of the first layer 30 at 323 K. In other words, the electrical conductivity σ may increase by the factor of 1.5 or even the factor of 2 in the when heating the first layer 30 from 323 K to 423 K.

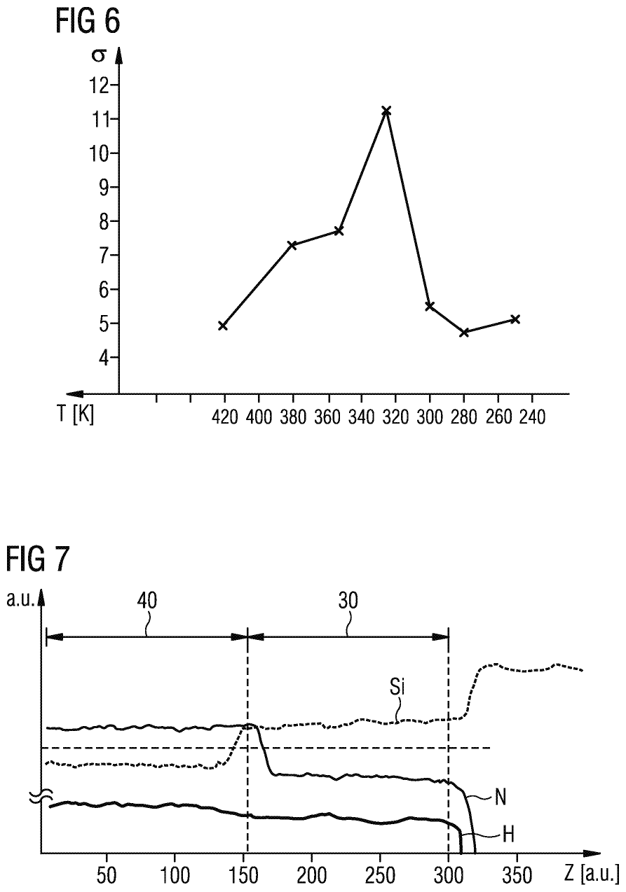

Now referring to FIG. 7, by way of example illustrates a ratio of different elements within the first layer 30 and the optional second layer in an embodiment of the semiconductor device 1 in atomic numbers. The respective share of the elements silicon Si, nitrogen N, and hydrogen H is depicted in arbitrary units on the y-axis of the graph against the depth along the vertical direction Z of the semiconductor device 1, the depth along the vertical direction Z being depicted on the x-axis of the graph. Layers 30 and 40 may exhibit a distribution as shown in FIG. 3. On the transition from the second layer 40 to the first layer 30, the share of silicon Si increases, while the share of nitrogen N decreases. The small overlap may occur due to constraints of the accuracy of the measurement. The concentration of hydrogen may stay at the same level in both layers 30, 40. In other embodiments, the share or concentration of hydrogen may even decrease at the transition from the second layer 40 to the first layer 30. For example, the content of hydrogen in atomic numbers may be 12+/−1 percent in the second layer 40 and 10+/−1 percent in the first layer 30.

It should be noted, that the atomic numbers and their respective share or concentration of the three elements N, Si, H have been determined with a (ToF-)SIMS measurement. Hence all values relating to atomic numbers in this application relate to this kind of measurement.

The beneficial electrical and chemical properties of the first layer 30 compared to non-stochiometric silicon nitride layers are linked to its hydrogen content. Therefore, the upper bounds for the hydrogen content provided in this application, is based on the insight that the desired properties of the first layer 30 are linked to hydrogen content below 16 percent and even better with a hydrogen content below 14 percent or even below 12 percent.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a semiconductor body comprising a first surface and a second surface;
an active region comprising at least one semiconductor cell configured to conduct a load current between the first surface and the second surface;
an edge termination region separating the active region from a chip edge; and
a first layer within at least a part of the edge termination region, the first layer comprising silicon, nitrogen and hydrogen,
wherein, in atomic numbers, a ratio of the silicon to the nitrogen is at least 3.3 to 4 in at least a portion of the first layer,
wherein at least the portion of the first layer comprises at most 16 percent hydrogen in atomic numbers.

2. The semiconductor device of claim 1, wherein the first layer comprises at most 13 percent hydrogen in atomic numbers.

3. The semiconductor device of claim 1, wherein the first layer is in direct contact to the semiconductor body.

4. The semiconductor device of claim 1, further comprising:
a second layer comprising silicon, nitrogen and hydrogen,
wherein, in atomic numbers, a ratio of the silicon to the nitrogen is lower in the second layer than in the first layer.

5. The semiconductor device of claim 1, wherein the first layer is an uppermost barrier layer in the edge termination region with no additional humidity resistant layer above the first layer.

6. A semiconductor device, comprising:
a semiconductor body comprising a first surface and a second surface;
an active region comprising at least one semiconductor cell configured to conduct a load current between the first surface and the second surface;
an edge termination region separating the active region from a chip edge; and
a first layer within the edge termination region, the first layer comprising silicon, nitrogen and hydrogen,
wherein an electrical conductivity of the first layer has a local or global maximum between 273 K and 373 K and/or the electrical conductivity of the first layer has a falling slope with increasing at a specified maximum working temperature.

7. The semiconductor device of claim 6, wherein the electrical conductivity of the first layer increases with increasing temperature in a temperature interval from 250 K to 300 K.

8. The semiconductor device of claim 6, wherein the electrical conductivity of the first layer decreases with increasing temperature in a temperature interval from 373 K to 473 K.

9. The semiconductor device of claim 6, wherein the electrical conductivity of the first layer at 323 K is at least 150% of the electrical conductivity of the first layer at 423 K.

10. The semiconductor device of claim 6, wherein a first portion of the first layer is connected to an electrically conductive first structure, and wherein the electrically conductive first structure has a same potential as a first load terminal arranged on the first surface of the semiconductor body.

11. The semiconductor device of claim 10, wherein a second portion of the first layer is connected to an electrically conductive second structure, and wherein the electrically conductive second structure has a same potential as a second load terminal arranged on the second surface of the semiconductor body.

12. The semiconductor device of claim 11, wherein a high-ohmic conducive path between the first structure and the second structure is formed by the first layer.

13. The semiconductor device of claim 6, wherein the first layer comprises a conductivity of at most 5×10⁻³ S within a temperature range from 273 K to 473 K.

14. The semiconductor device of claim 6, wherein the first layer comprises a conductivity of at least 1×10⁻⁴ S or at least 2×10⁻² S.

15. The semiconductor device of claim 6, wherein the first layer has a thickness of 40 nm to 800 nm.

16. The semiconductor device of claim 6, wherein the first layer is formed as a contiguous layer, and wherein the first layer is the only layer of its specific chemical composition.

17. The semiconductor device of claim 6, further comprising:
a third layer in direct contact to the semiconductor body,
wherein the first layer is arranged at least partly above the third layer.

18. The semiconductor device of claim 6, wherein the first layer is in direct contact to the semiconductor body.

19. The semiconductor device of claim 6, further comprising:
a second layer comprising silicon, nitrogen and hydrogen,
wherein, in atomic numbers, a ratio of the silicon to the nitrogen is lower in the second layer than in the first layer.

20. A semiconductor device, comprising:
a semiconductor body comprising a first surface and a second surface;
an active region comprising at least one semiconductor cell configured to conduct a load current between the first surface and the second surface;
an edge termination region separating the active region from a chip edge;
a first layer at least within the edge termination region, the first layer comprising silicon, nitrogen and hydrogen; and
a second layer at least within the edge termination region, the second layer comprising silicon, nitrogen and hydrogen,
wherein, in atomic numbers, a ratio of the silicon to the nitrogen is at least 10 percent higher in the first layer than in the second layer.

21. The semiconductor device of claim 20, wherein the second layer comprises at most 16 percent hydrogen in atomic numbers.

22. The semiconductor device of claim 20, wherein the second layer is arranged above the first layer.

23. The semiconductor device of claim 20, wherein the first layer is an uppermost barrier layer in the edge termination region with no additional humidity resistant layer above the first layer.

24. A semiconductor device, comprising:
a semiconductor body comprising a first surface and a second surface;
a first load terminal arranged on the first surface;
a second load terminal arranged on the second surface;
an active region comprising at least one semiconductor cell configured to conduct a load current between the first load terminal and the second load terminal;
a chip edge bordering the first surface and the second surface;
an edge termination region arranged between the active region and the chip edge, the edge termination region comprising an edge termination structure; and
above the first load terminal and/or above the edge termination structure, a first layer comprising silicon, nitrogen and hydrogen,
wherein, in at least a portion of the first layer, a number of silicon atoms is greater than 82.5% of a number of nitrogen atoms,
wherein of all the silicon atoms, nitrogen atoms and hydrogen atoms within at least the portion of the first layer, at most 12% are hydrogen atoms.

25. A method for manufacturing a semiconductor device, the method comprising:
providing a semiconductor body comprising a first surface, a second surface, an active region comprising at least one semiconductor cell configured to conduct a load current between the first surface and the second surface, and an edge termination region separating the active region from a chip edge; and
forming a first layer within the edge termination region, the first layer comprising silicon, nitrogen and hydrogen,
wherein, in atomic numbers, a ratio of the silicon to the nitrogen is at least 3.3 to 4 in at least a portion of the first layer,
wherein at least the portion of the first layer comprises at most 16 percent hydrogen in atomic numbers.
